(19) United States
(12) Patent Application Publication
(10) Pub. No.: US 2026/0185264 A1
(43) Pub. Date: Jul. 2, 2026

(54) CRYSTAL GROWTH APPARATUS

(71) Applicant: METAL INDUSTRIES RESEARCH & DEVELOPMENT CENTRE, KAOHSIUNG (TW)

(72) Inventors: Jhong Cin HONG, Tainan City (TW); Chang-Sin YE, Tainan City (TW)

(21) Appl. No.: 19/001,593

(22) Filed: Dec. 26, 2024

(51) Int. Cl. C30B 23/06; C30B 35/00

(52) U.S. Cl. CPC C30B 23/066; C30B 35/002

(57) ABSTRACT

A crystal growth apparatus includes a crucible, an upper cover, a first coil, a second coil, a third coil, a first power supply unit, a second power supply unit and a third power supply unit. The crucible is configured to accommodate a crystal growth material. The upper cover is on the top of the crucible, forms a reaction space with the crucible, in which the upper cover is configured to carry a crystal seed formed by the crystal growth apparatus. The first, second and third coils surround the crucible and are arranged sequentially from top to bottom in a vertical direction. The first power supply unit is electrically coupled to the first coil. The second power supply unit is electrically coupled to the second coil. The third power supply unit is electrically coupled to the third coil.

### BACKGROUND

### Technical Field

The present disclosure relates to a crystal growth apparatus.

### Description of Related Art

With the booming of electric vehicles, renewable energy, and industrial power applications, wafers have become a basic necessity. Wafers are grown by a method such as physical vapor transport (PVT). The method typically utilizes electromagnetic induction of a single-winding induction heating coil to heat a crucible in a crystal growth apparatus. However, due to the skin effect for a current, the heat energy generated by electromagnetic induction is concentrated mainly on the side walls and the bottom of the crucible. Furthermore, a single set of coils in standalone may not be able to regulate the heating temperature of each position of the crucible, resulting in difficulty for the crucible to have a proper axial temperature gradient. An excessive axial temperature gradient may obstruct a sublimated gas from transferring to a crystal seed area of the upper cover of the crucible, and in turn, the sublimation gas is deposited on the surface of the crystal growth material instead of the upper cover of the crucible.

### SUMMARY

In one aspect of the present disclosure, a crystal growth apparatus is provided. By replacing single-winding induction heating coils with plural sets of induction heating coils, heating temperatures of different positions in a crucible may be individually controlled, making the crucible have a proper axial temperature gradient. Furthermore, distances between the plural sets of induction heating coils may be individually controlled, making the different positions in the crucible have better heating temperatures at various stages of a crystal growth process. Therefore, the crystal growth apparatus may instantaneously adjust the distances between the plural sets of induction heating coils according to a dynamic process of the crystal growth, so that the temperature gradient in the crucible may be precisely controlled. Thus, the crystal growth apparatus may have advantages such as reducing losses of circuit components, lowering electricity consumption, and improving the quality of the crystal growth.

Some embodiments of the present disclosure provide a crystal growth apparatus. The crystal growth apparatus includes a crucible, an upper cover, a first coil, a second coil, a third coil, a first power supply unit, a second power supply unit, and a third power supply unit. The crucible is configured to accommodate a crystal growth material. The upper cover is on the top of the crucible, forms a reaction space with the crucible, in which the upper cover is configured to carry a crystal seed formed by the crystal growth apparatus. The first, second, and third coils surround the crucible, and are arranged sequentially from top to bottom in a vertical direction. The first power supply unit is electrically coupled to the first coil. The second power supply unit is electrically coupled to the second coil. The third power supply unit is electrically coupled to the third coil.

According to some embodiments of the present disclosure, a first distance between the first and second coils is different from a second distance between the second and third coils.

According to some embodiments of the present disclosure, the first coil includes a coil pitch, and the first distance is greater than the coil pitch.

According to some embodiments of the present disclosure, the coil pitch of the first coil is substantially the same as a coil pitch of the second coil.

According to some embodiments of the present disclosure, the crystal growth apparatus further includes a first vertical position control unit, a second vertical position control unit, and a third vertical position control unit. The first vertical position control unit is coupled to the first coil, and configured to move the first coil along the vertical direction. The second vertical position control unit is coupled to the second coil, and configured to move the second coil along the vertical direction. The third vertical position control unit is coupled to the third coil, and configured to move the third coil along the vertical direction.

According to some embodiments of the present disclosure, the second coil is moved to align with a melting level of the crystal growth material.

According to some embodiments of the present disclosure, the first coil is moved to align a nucleation surface of the crystal seed.

According to some embodiments of the present disclosure, the first, second, and third power supply units share an alternating current power generation unit, in which the power of the alternating current power generation unit is between 60 Hz and 1 MHz, and the first, second, and third power supply units respectively include first, second, and third power matching units that are coupled to the alternating current power generation unit.

According to some embodiments of the present disclosure, the power of the second power supply unit is different from the power of the first power supply unit.

According to some embodiments of the present disclosure, a first relative distance is between center lines of the first and second coils, and a second relative distance is between a center line of the third coil and a bottom part of the crucible, in which the first relative distance is different from the second relative distance.

### BRIEF DESCRIPTION OF THE DRAWINGS

FIG. 1A is a schematic diagram of a crystal growth apparatus in accordance with some embodiments of the present disclosure.

FIG. 1B is a temperature versus vertical position graph of a crystal growth apparatus in accordance with some embodiments of the present disclosure.

FIG. 2 is a schematic diagram of a crystal growth apparatus in accordance with some embodiments of the present disclosure.

FIG. 3 is a schematic diagram of a crystal growth apparatus in accordance with some embodiments of the present disclosure.

FIGS. 4A-4D are schematic diagrams of the crystal growth apparatus in FIG. 3 at various stages of the crystal growth process.

### DETAILED DESCRIPTION

The embodiments of the present disclosure are discussed in detail below. However, it should be understood that the embodiments provide many applicable concepts that can be implemented in a wide variety of specific contexts. The embodiments discussed and disclosed are for illustrative purposes only and are not intended to limit the scope of the present disclosure. As used herein, the terms “first,” “second,” etc., do not specifically refer to an order or a sequence, but are intended only to distinguish components or operations that are described in the same technical terms.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “substantially” shall generally mean within 20 percent, or within 10 percent, or within 5 percent of a given value or range. Numerical quantities given herein are approximate, meaning that the term “substantially” can be inferred if not expressly stated.

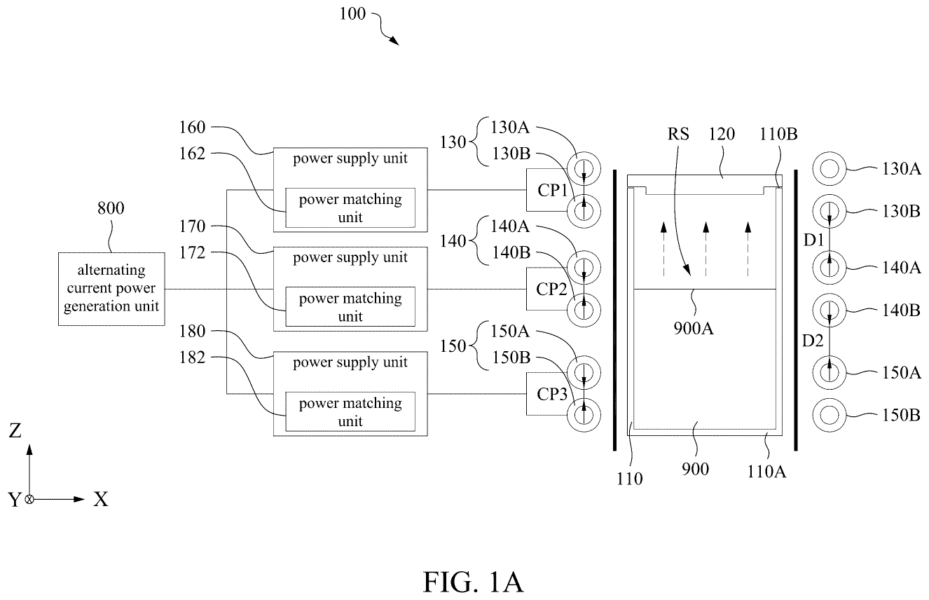

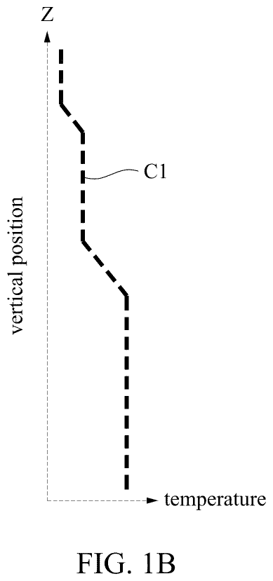

Referring to FIGS. 1A and 1B, FIG. 1A is a schematic diagram of a crystal growth apparatus 100 in accordance with some embodiments of the present disclosure, and FIG. 1B is a graph of temperature versus vertical position for the crystal growth apparatus 100. The crystal growth apparatus 100 includes a crucible 110, an upper cover 120, coils 130, 140, and 150, and power supply units 160, 170, and 180. The crystal growth apparatus 100 may be applied for fabrication of wafers of semiconductor, a similar material, or a combination thereof. For example, in the present embodiment, the crystal growth apparatus 100 may fabricate a semiconductor wafer by a physical vapor transport (PVT) method, similar crystal growth methods, or a combination thereof.

In some embodiments, the crucible 110 may be made of any material with a high melting point. For example, in some embodiments, the crucible 110 may be graphite, graphite with a graphene layer, graphite with a tantalum hafnium carbide layer, graphite with a carbide layer, similar materials, or a combination thereof. A bottom portion 110A of the crucible 110 is configured to accommodate a crystal growth material 900 which may be a pure element material, such as silicon, or may be compound materials, e.g., silicon carbide, similar materials, or a combination thereof.

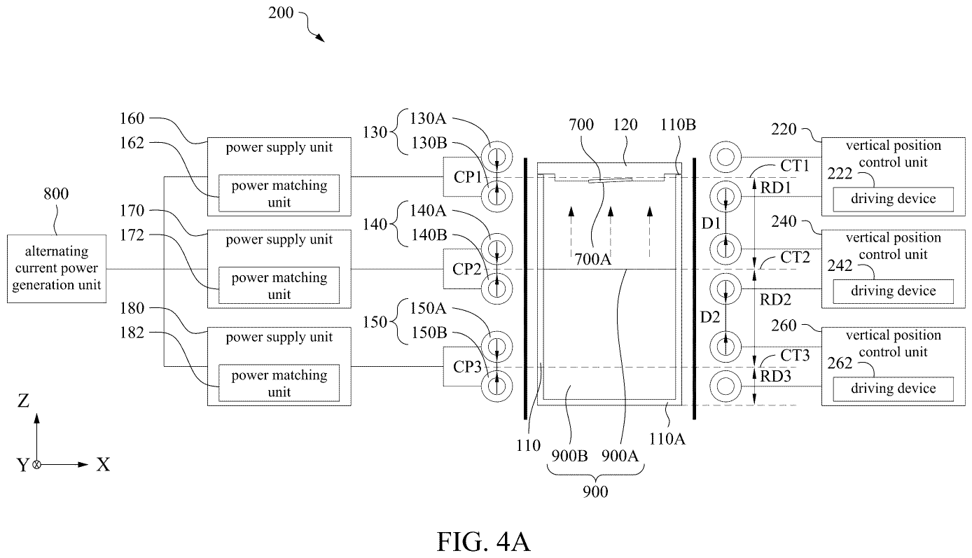

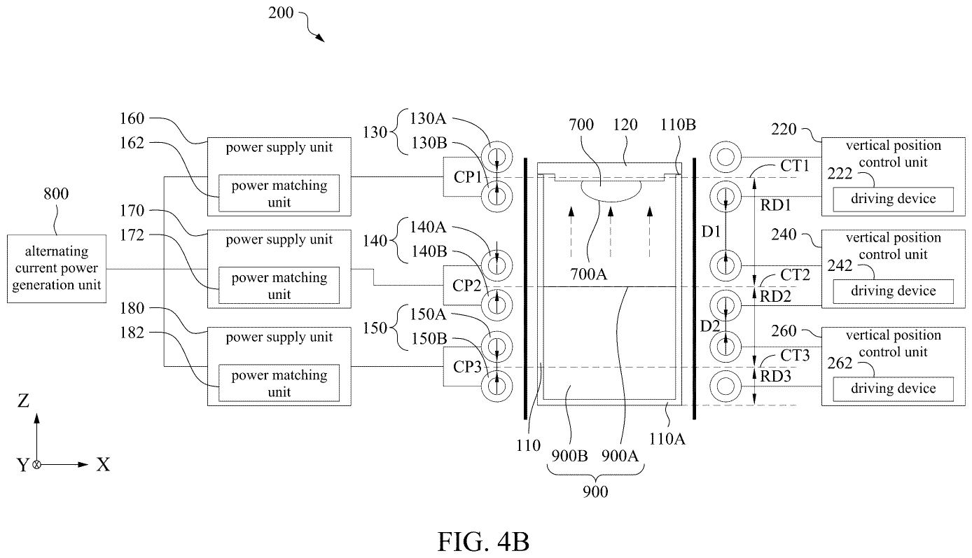

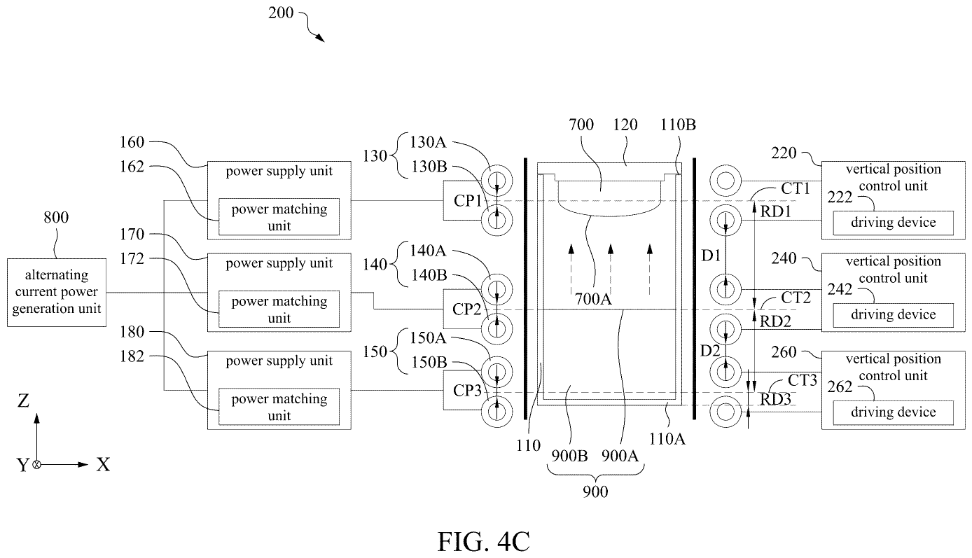

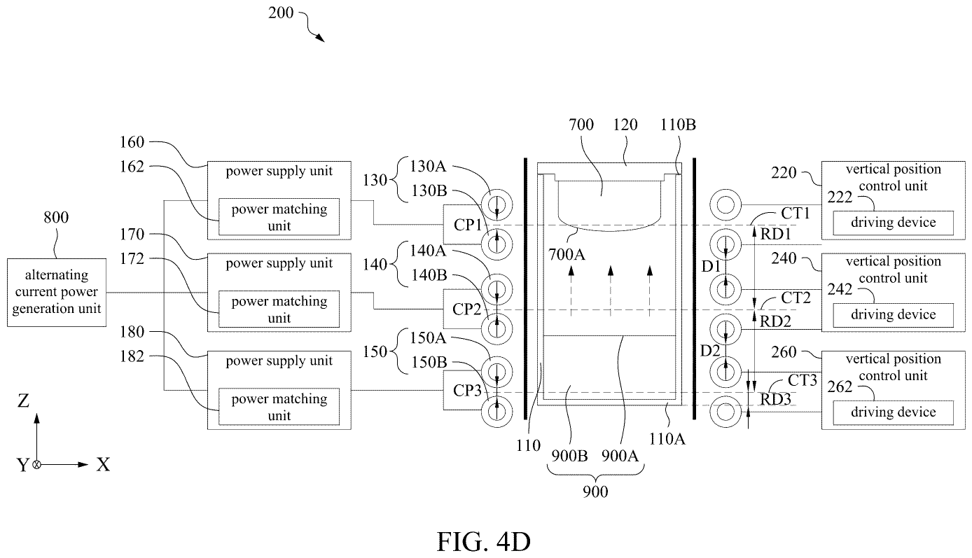

In some embodiments, the upper cover 120 may be configured to carry a crystal seed 700 (shown in FIGS. 4A and 4D) that is formed by the crystal growth apparatus 100. The upper cover 120 may be fabricated from the same material as the crucible 110. For example, in some embodiments, the crucible 110 and the upper cover 120 may be fabricated from graphite. In another embodiment, the upper cover 120 may be fabricated from the material different from the crucible 110. For example, in some embodiments, the crucible 110 may be fabricated from graphite, and the upper cover 120 may be fabricated from graphite with a carbide layer.

In some embodiments, the upper cover 120 may be on the top portion 110B of the crucible 110, and form a reaction space RS with the crucible 110. The reaction space RS may have the crystal growth material 900 (e.g., silicon carbide) heated, sublimated into vapor, and transferred to a crystal seed area (e.g., the upper cover 120) to deposit crystals. For example, according to the curve C1 shown in FIG. 1B, the temperature of the bottom portion 110A of the crucible 110 in the reaction space RS is the highest, which is beneficial to heat, and sublimate the crystal growth material 900 into vapor. The temperature of a melting level 900A of the crystal growth material 900 in the reaction space RS is between the bottom portion 110A of the crucible 110 and the upper cover 120, which is beneficial to transfer the vapor of the crystal growth material 900 to the upper cover 120. The temperature of the upper cover 120 is the lowest, which helps the vapor of the crystal growth material 900 grown into the crystal seed 700 at the upper cover 120 (shown in FIGS. 4A and 4D).

In various embodiments, the coils 130, 140, and 150 may be fabricated from the same material or different material (e.g., copper, aluminum, or another suitable material). For example, in some embodiments, the coils 130, 140, and 150 may be fabricated from copper. In the other embodiment, the coils 130, 140, and 150 may be respectively and independently fabricated from copper or aluminum.

The coils 130, 140, and 150 may surround the crucible 110, and be arranged from top to bottom in a vertical direction (i.e., the direction Z). The distance D1 between the coils 130 and 140, and the distance D2 between the coils 140 and 150 may be adjusted according to functional requirements. For example, in some embodiments, the distances D1 and D2 are substantially the same. In the other embodiments, the distances D1 and D2 are substantially different. However, it should be noticed that the distance D1 between the coils 130 and 140 needs to be larger than or equal to the circuit pitch CP1 between the first turn 130A and the second turn 130B of the coil 130 or the circuit pitch CP2 between a first turn 140A and the second turn 140B of the coil 140 to avoid the electromagnetic interference between the coils, thus affecting the heating performance of the crystal growth apparatus 100. Furthermore, the distance D2 between the coils 140 and 150 needs to be larger than or equal to the circuit pitch CP2 between the first turn 140A and the second turn 140B of the coil 140 or the circuit pitch CP3 between the first turn 150A and the second turn 150B of the coil 150 to avoid the electromagnetic interference between the coils that affects the heating performance of the crystal growth apparatus 100.

The number of turns of the coils 130, 140, and 150 may be adjusted according to functional requirements related to the heating power of the coils. For example, the drawings of the present disclosure illustrate that the number of turns of each of the coils 130, 140, and 150 is 2. In some other embodiments, the number of turns of the coils 130, 140, and 150 may be designed to be 2 to 10. In various embodiments, the number of turns of the coils 130, 140, and 150 may be the same as each other or different from each other.

A suitable power may be independently supplied to the coils 130, 140, and 150 according to the number of turns of the coils 130, 140, and 150. For example, the power ratio of the coils 130, 140, and 150 may be designed to be 3:4:3 respectively when a turn ratio of the coils 130, 140, and 150 is 2:3:2 respectively as the total power is unchanged and the circuit pitches CP1, CP2, and CP3 of the coils 130, 140, and 150 are all the same, resulting in the coils 130, 140, and 150 having different temperatures. Therefore, the coils 130, 140, and 150 may be adjusted to be different temperatures according to the crystal growth process, so that the crucible 110 has a great temperature gradient.

The circuit pitches CP1, CP2, and CP3 of the coils 130, 140, and 150 may be adjusted according to functional requirements related to the heating power of the coils. For example, in some embodiments, the circuit pitch CP1 between the first turn 130A and the second turn 130B of the coil 130 is between 5 mm and 100 mm. The circuit pitch CP2 between the first turn 140A and the second turn 140B of the coil 140 is between 5 mm and 100 mm. The circuit pitch CP3 between the first turn 150A and the second turn 150B of the coil 150 is between 5 mm and 100 mm. In various embodiments, the circuit pitch CP1, CP2, and CP3 respective of the coils 130, 140, and 150 may be the same as or different from each other.

A suitable power may be independently supplied to the coils 130, 140, and 150 according to the number of turns of the coils 130, 140, and 150. For example, in the present embodiment, the power ratio of the coils 130, 140, and 150 may respectively be designed to be 3:3:4 when the ratio of circuit pitches CP1, CP2, and CP3 of the coils 130, 140, and 150 is 3:2:3 as the total power is unchanged and the circuit pitches CP1, CP2, and CP3 of the coils 130, 140, and 150 are all the same. Therefore, the coils 130, 140, and 150 may be adjusted to be different temperatures as the total power is unchanged, resulting in the crucible 110 having a great temperature gradient.

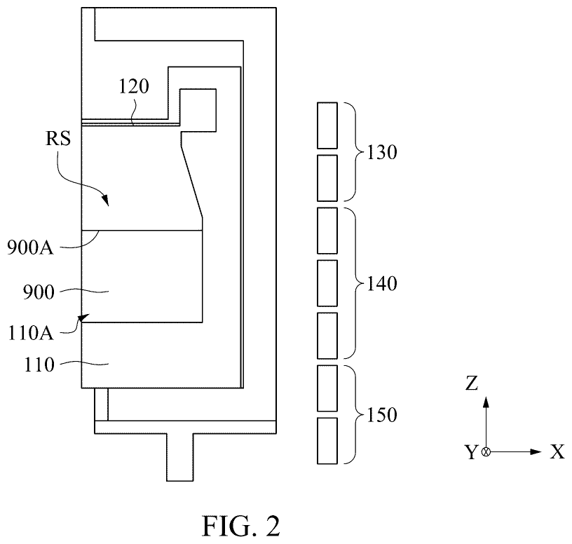

Furthermore, in another embodiment, the number of the turns of the coils 130, 140, and 150 and the circuit pitches CP1, CP2, and CP3 may be simultaneously designed. Referring to FIG. 2, FIG. 2 is a schematic diagram of the crystal growth apparatus 100 in accordance with some embodiments of the present disclosure. In the present embodiment, the circuit pitch CP1 between the first turn 130A and the second turn 130B of the coil 130, the circuit pitch CP2 between the first turn 140A and the second turn 140B of the coil 140, and the circuit pitch CP3 between the first turn 150A and the second turn 150B of the coil 150 are all substantially the same, and the ratio of the number of turns of the coils 130, 140, and 150 may be 2:3:2. Therefore, the power of the coil 140 may be larger than the power of the coils 130 and 150 as other conditions remain unchanged. For example, the power ratio of the coils 130, 140, and 150 may be 3:4:3 in sequence. Therefore, the coils 130, 140, and 150 may have different temperatures according to the crystal growth process, so that the crucible 110 has a great temperature gradient.

Referring back to FIGS. 1A and 1B. In various embodiments, the power supply units 160, 170, and 180 are respectively configured to provide electrical powers to the coils 130, 140, and 150. The power supply units 160, 170, and 180 may share the alternating current power generation unit 800 and the power supply units 160, 170, and 180 respectively include power matching units 162, 172, and 182. The power matching units 162, 172, and 182 are configured to regulate the power factor and the maximum power transmission rate of the alternating current power generation unit 800 to adjust the electrical powers supplied to the coils 130,140, and 150 by the power supply units 160, 170, and 180. The alternating current power generation unit 800 has an alternating current power frequency range between 60 Hz and 1 MHz. Therefore, the heating temperature of the coils 130, 140, and 150 of the crystal growth apparatus 100 may be respectively controlled. For example, in some embodiments, at a first time point, the frequencies of the power supply units 160, 170, and 180 are about the same (e.g., 10 kHz), and respectively provide electrical powers of 4 kW, 5 kW, and 6 kW to the coils 130, 140, and 150, in which the circuit pitches CP1, CP2, and CP3 of the coils 130, 140, and 150 are all the same. At a second time point different from the first time point, the frequencies of the power supply units 160, 170, and 180 are about the same (e.g., 10 kHz), but the power of the power supply units 160, 170, and 180 at the second time point is individually different from that of the power supply units 160, 170, and 180 at the first time point, so that the power of the coils 130, 140, and 150 at the second time point is different from that of the coils 130, 140, and 150 corresponding to the first time point. In another embodiment, the frequency of the power supply units 160 is different from the frequencies of the power supply units 170 or 180 (for example, the frequencies of the power supply units 160, 170, and 180 are respectively 10 kHz, 9 kHz, and 8 kHz), and all of the power supply units 160, 170, and 180 supply electrical powers of 5 kW to the coils 130, 140, and 150, in which the circuit pitches CP1, CP2, and CP3 of the coils 130, 140, and 150 are all the same. Therefore, compared to single-winding induction heating coils, the coils 130, 140, and 150 may achieve the same temperature gradient distribution under lower electricity consumption. In addition, in the present embodiment, the power supply units 160, 170, and 180 may share the alternating current power generation unit 800 as an example. In some embodiments, the power supply units 160, 170, and 180 may respectively be electrically connected to independent alternating current power generation units. The power supply units 160, 170, and 180 are not limited to those shown in the drawings.

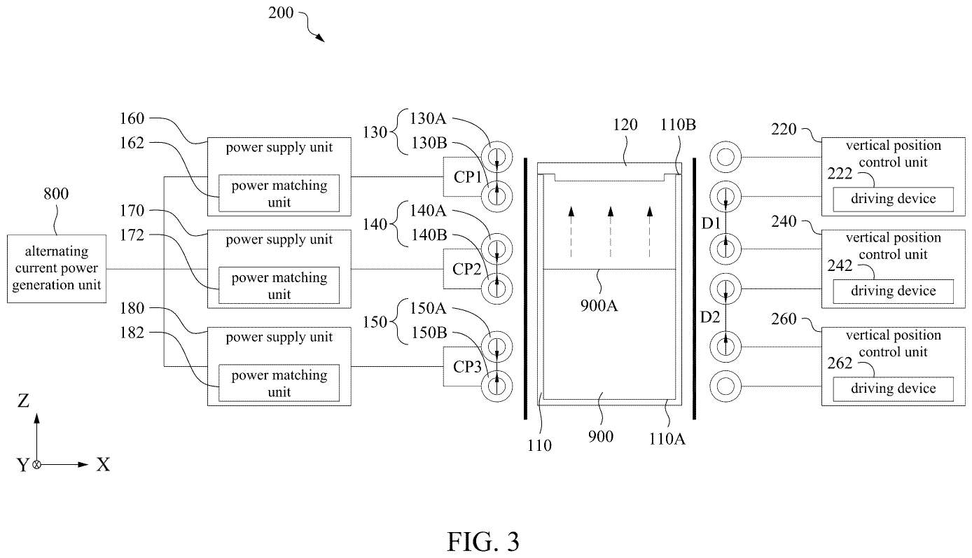

Referring FIG. 3, FIG. 3 is a schematic diagram of a crystal growth apparatus 200 in accordance with some embodiments of the present disclosure. The crystal growth apparatus 200 in FIG. 3 is similar to the crystal growth apparatus 100 in FIG. 1A. The differences between the FIGS. 3 and 1 are as follows. In the crystal growth apparatus 200, vertical position control units 220, 240, and 260 are respectively coupled to the coils 130, 140, and 150, and are configured to move the coils 130, 140, and 150 in the vertical direction (i.e., the direction Z). The vertical position control units 220, 240, and 260 respectively include driving devices 222, 242, and 262. The driving device 222 may be linear motor, stepping motor, servo motor, similar motors, or a combination thereof. In various embodiments, the driving devices 222, 242, and 262 may be the same or different. The movement speeds of the vertical position control units 220, 240, and 260 may be adjusted according to the crystal growth process. For example, in the present embodiment, the vertical position control units 220, 240, and 260 may be respectively move the coils 130, 140, and 150 once every twelve hours according to the crystal growth process of silicon carbide, in which movements of the coils 130, 140, and 150 may be between 0.1 mm and 1 mm. Therefore, the distance D1 between the coils 130 and 140 and the distance D2 between the coils 140 and 150 may be adjusted according to the crystal growth process.

FIGS. 4A-4D are schematic diagrams of the crystal growth apparatus 200 in FIG. 3 at various stages of the crystal growth process. First, refer to FIG. 4A. The coils 130, 140, and 150 are disposed at the designed heating positions. For example, in the present embodiment, the center line CT1 between the first turn 130A and the second turn 130B of the coil 130 may be substantially aligned with a nucleation surface 700A of the crystal seed 700 by the vertical position control unit 220 by a method such as manual control or programmed control to heat the crystal seed 700. The center line CT2 between the first turn 140A and the second turn 140B of the coil 140 may be substantially aligned with the melting level 900A of the crystal growth material 900 by the vertical position control unit 240 to heat the crystal growth material 900. The center line CT3 between the first turn 150A and the second turn 150B of the coil 150 may be aligned with a portion 900B of the crystal growth material 900 by the vertical position control unit 260 to heat the crystal growth material 900. Furthermore, the temperature of the coil 140 may be designed to be larger than the temperature of the coil 150, and the temperature of the coil 150 may be designed to be larger than the temperature of the coil 130. Therefore, the crystal growth apparatus 100 may have a proper temperature gradient that may effectively improve the steam propulsion force of the sublimated gas of the crystal growth material 900, and be beneficial to transfer the sublimated gas of the crystal growth material 900 to the upper cover 120 to deposit crystals.

In addition, the relative distance RD1 between the center line CT1 that is right between the first turn 130A and the second turn 130B of the coil 130 and the center line CT2 that is right between the first turn 140A and the second turn 140B of the coil 140 is larger than the distance D1 between the coils 130 and 140. The relative distance RD2 between the center line CT2 that is right between the first turn 140A and the second turn 140B of the coil 140 and the center line CT3 that is right between the first turn 150A and the second turn 150B of the coil 150 is larger than the distance D2 between the coils 140 and 150. There is the relative distance RD3 between the center line CT3 that is right between the first turn 150A and the second turn 150B of the coil 150 and the bottom portion 110A of the crucible 110. In the present embodiment, the relative distance RD2 is larger than or equal to the relative distance RD1, and the relative distance RD1 is larger than the relative distance RD3. Therefore, the coils 130, 140, and 150 may have maximum downward movement distances (for example, the maximum downward movement distance of the coil 130 may be a half of the relative distance RD1 subtracted by a half of the minimum value of the distance D1) while avoiding the impact of high voltage arc and magnetic field loss caused by disposing the coils 130, 140, and 150 too close to each other.

Next, please refer to FIG. 4B. The coils 130, 140, and 150 may be moved according to the crystal growth stage and/or the crystal growth time during the crystal growth process. For example, in the present embodiment, the coil 130 may be gradually moved downward along the vertical direction (i.e., the direction Z) by the vertical position control unit 220 to align the center line CT1 of the first turn 130A and the second turn 130B of the coil 130 with the nucleation surface 700A of the crystal seed 700 by a method such as manual control or programmed control as the nucleation surface 700A of the crystal seed 700 gradually approaches the melting level 900A of the crystal growth material 900 along the vertical direction (i.e., the direction Z). The coil 140 may be gradually moved downward along the vertical direction (i.e., the direction Z) by the vertical position control unit 240 to keep the center line CT2 of the first turn 140A and the second turn 140B of the coil 140 substantially aligned with the melting level 900A of the crystal growth material 900 by a method such as manual control or programmed control as the melting level 900A of the crystal growth material 900 gradually decreases during the crystal growth process. In FIG. 4B, the center line CT3 between the first turn 150A and the second turn 150B of the coil 150 keeps aligned with the portion 900B of the crystal growth material 900, in which the relative distance RD1 is larger than the relative distance RD2, and the relative distance RD2 is larger than the relative distance RD3.

Next, please refer to FIG. 4C. For example, in the present embodiment, the coil 130 may be gradually moved downward along the vertical direction (i.e., the direction Z) by the vertical position control unit 220 to keep the center line CT1 of the first turn 130A and the second turn 130B of the coil 130 substantially aligned with the nucleation surface 700A of the crystal seed 700 as the nucleation surface 700A of the crystal seed 700 gradually approaches the melting level 900A of the crystal growth material 900 along the vertical direction (i.e., the direction Z). The coil 140 may be gradually moved downward along the vertical direction (i.e., the direction Z) by the vertical position control unit 240 to keep the center line CT2 of the first turn 140A and the second turn 140B of the coil 140 substantially aligned with the melting level 900A of the crystal growth material 900 as the melting level 900A of the crystal growth material 900 decreases along the vertical direction (i.e., the direction Z). The coil 150 may be moved downward along the vertical direction (i.e., the direction Z) by the vertical position control unit 260 by a method such as manual control or programmed control to move the center line CT3 of the first turn 150A and the second turn 150B of the coil 150 toward the bottom portion 110A of the crucible 110, thus shrinking the relative distance RD3. Therefore, the relative distance RD1 is larger than the relative distance RD2, and the relative distance RD2 is larger than the relative distance RD3, and the distance D2 between the coils 140 and 150 may remain larger than the circuit pitch CP2 of the coil 140 or the circuit pitch CP3 of the coil 150.

Next, please refer to FIG. 4D. For example, in the present embodiment, the coil 130 may be further moved downward along the vertical direction (i.e., the direction Z) by the vertical position control unit 220 to keep the center line CT1 of the first turn 130A and the second turn 130B of the coil 130 substantially aligned with the nucleation surface 700A of the crystal seed 700 as the nucleation surface 700A of the crystal seed 700 further approaches the melting level 900A of the crystal growth material 900 along the vertical direction (i.e., the direction Z). The coil 140 may be further moved downward along the vertical direction (i.e., the direction Z) by the vertical position control unit 240 to further shrink the relative distance RD2 as the melting level 900A of the crystal growth material 900 further decreases along the vertical direction (i.e., the direction Z). At this time, the distance D2 may be substantially shrunk to the minimum value of the distance D2 (for example, the distance D2 may be substantially the same as the circuit pitches CP2 or CP3). The coil 150 may be further moved downward along the vertical direction (i.e., the direction Z) by the vertical position control unit 260 by a method such as manual control or programmed control to move the center line CT3 of the first turn 150A and the second turn 150B of the coil 150 toward the bottom portion 110A of the crucible 110, thus further shrinking the relative distance RD3 of the coil 150. Therefore, the coils 130, 140, and 150 may be further moved downward to have the relative distance RD1 be substantially larger than or equal to the relative distance RD2, and to have the relative distance RD2 be substantially larger than or equal to the relative distance RD3. The distance D1 between the coils 130 and 140 is substantially the same as the circuit pitch CP1 of the coil 130 or the circuit pitch CP2 of the coil 140. The distance D2 between the coils 140 and 150 is substantially the same as the circuit pitch CP2 of the coil 140 or the circuit pitch CP3 of the coil 150. Therefore, the heating performance of the coils 130, 140, and 150 may be maximized at the final stage of the crystal growth process. It should be noticed that the number of turns of the coils illustrated in FIGS. 4A-4D is for the illustrative purposes only, and in various embodiments, the coils of the present invention may independently have a greater number of the turns. In which, the distances described in the present invention may take the center lines of the coils as the starting point or the ending point while the coils have a greater number of the turns.

According to some embodiments of the present disclosure, a crystal growth apparatus is provided. By replacing single-winding induction heating coils with plural sets of induction heating coils, heating temperatures of different positions in a crucible may be individually controlled, making the crucible have a proper axial temperature gradient. Furthermore, distances between the plural sets of induction heating coils may be individually controlled, making the different positions in the crucible have better heating temperatures at various stages of a crystal growth process. Therefore, the crystal growth apparatus may instantaneously adjust the distances between the plural sets of induction heating coils according to a dynamic process of the crystal growth, so that the temperature gradient in the crucible may be precisely controlled. Thus, the crystal growth apparatus may have advantages such as reducing losses of circuit components, lowering electricity consumption, and improving the quality of the crystal growth.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A crystal growth apparatus, comprising:
a crucible, wherein the crucible is configured to configured to accommodate a crystal growth material;
an upper cover on a top portion of the crucible, and forming a reaction space with the crucible, wherein the upper cover is configured to carry a crystal seed formed by the crystal growth apparatus;
first, second, and third coils surrounding the crucible, and arranged sequentially from top to bottom in a vertical direction;
a first power supply unit electrically coupled to the first coil;
a second power supply unit electrically coupled to the second coil; and
a third power supply unit electrically coupled to the third coil.

2. The crystal growth apparatus of claim 1, wherein a first distance between the first and second coils is different from a second distance between the second and third coils.

3. The crystal growth apparatus of claim 2, wherein the first coil comprises a coil pitch, and the first distance is greater than the coil pitch.

4. The crystal growth apparatus of claim 3, wherein the coil pitch of the first coil is substantially the same as a coil pitch of the second coil.

5. The crystal growth apparatus of claim 1, further comprising:
a first vertical position control unit coupled to the first coil, and configured to move the first coil along the vertical direction;
a second vertical position control unit coupled to the second coil, and configured to move the second coil along the vertical direction; and
a third vertical position control unit coupled to the third coil, and configured to move the third coil along the vertical direction.

6. The crystal growth apparatus of claim 1, wherein the second coil is moved to align a melting level of the crystal growth material.

7. The crystal growth apparatus of claim 1, wherein the first coil is moved to align with a nucleation surface of the crystal seed.

8. The crystal growth apparatus of claim 1, wherein the first, second, and third power supply units share an alternating current power generation unit, wherein power of the alternating current power generation unit is between 60 Hz and 1 MHz, and the first, second, and third power supply units respectively comprise first, second, and third power matching units that are coupled to the alternating current power generation unit.

9. The crystal growth apparatus of claim 1, wherein power of the second power supply unit is different from power of the first power supply unit.

10. The crystal growth apparatus of claim 1, wherein a first relative distance is between center lines of the first and second coils, and a second relative distance is between a center line of the third coil and a bottom part of the crucible, wherein the first relative distance is different from the second relative distance.
